(19) United States
(12) Patent Application Publication
(10) Pub. No.: US 2025/0015039 A1
(43) Pub. Date: Jan. 9, 2025

(54) BONDING DEVICE AND BONDING METHOD

(71) Applicant: TORAY ENGINEERING CO., LTD., Tokyo (JP)

(72) Inventors: Tatsuya OKADA, Kyoto-shi (JP); Koichi KAZAMA, Otsu-shi (JP); Toshiyuki JINDA, Kusatsu-shi (JP); Yoshiyuki ARAI, Otsu-shi (JP)

(21) Appl. No.: 18/892,975

(22) Filed: Sep. 23, 2024

Related U.S. Application Data
(63) Continuation of application No. PCT/JP2023/012288, filed on Mar. 27, 2023.

(30) Foreign Application Priority Data
Mar. 28, 2022 (JP) 2022-051064

(51) Int. Cl. H01L 23/00; H01L 21/67

(52) U.S. Cl. CPC H01L 24/74; H01L 21/67144; H01L 24/80; H01L 2224/75101; H01L 2224/75263; H01L 2224/7565; H01L 2224/7598; H01L 2224/80054; H01L 2224/80201; H01L 2224/80224

(57) ABSTRACT

A bonding device is configured to bond a first element and a second element. The bonding device comprises an activating unit configured to activate a first bonding surface, which is a bonding surface of the first element, and a second bonding surface, which is a bonding surface of the second element, and a bonding unit configured to irradiate an active energy ray to cause the first bonding surface and the second bonding surface to come closer and bond with each other, from a state in which the first bonding surface and the second bonding surface face each other with a prescribed gap therebetween.

### CROSS-REFERENCE TO RELATED APPLICATIONS

This application is a continuation application of PCT International Application No. PCT/JP2023/012288 filed on Mar. 27, 2023, which claims priority to Japanese Patent Application No. 2022-051064 filed on Mar. 28, 2022 with Japan Patent Office. The entire disclosures of PCT International Application No. PCT/JP2023/012288 and Japanese Patent Application No. 2022-051064 are hereby incorporated herein by reference.

### BACKGROUND

### Field of the Invention

The present invention relates to a bonding device and a bonding method for bonding a semiconductor chip and a wiring substrate so as to be electrically connected.

### Background Information

One technique for bonding materials together is hybrid bonding. Hybrid bonding is a technique for bonding surfaces, on each of which electrode patterns and insulating layers are both present. At this time, as indicated in Japanese Patent No. 6448656 (Patent Document 1), surfaces to be bonded are activated by plasma, for example, and brought into contact with each other, thereby causing electron orbits of the two surfaces to overlap and forming a bond. By activating, and then bonding, the bonding surfaces in this manner, it is possible to carry out bonding at room temperature and to ignore thermal deformation, so this method is suitable when bonding materials that have a narrow-pitch electrode pattern.

### SUMMARY

However, it is difficult to bring bonding surfaces in contact with each other in an activated state using conventional bonding devices. Specifically, if the materials to be bonded are semiconductor chips and a wiring substrate, when mounting, onto the wiring substrate, some of a large number of semiconductor chips arranged on a carrier substrate, conventionally, the target semiconductor chips are picked up from the carrier substrate, the front and back sides of the semiconductor chips are inverted, and the semiconductor chips are transported toward the wiring substrate so that the two bonding surfaces face each other. On the other hand, if the two bonding surfaces are activated, when holding the bonding surface side of the semiconductor chip, it is necessary to use a special transport hand, such as a Bernoulli chuck, because the bonding surface should not come in contact with the transport hand. In addition, when removing the chip from the carrier substrate side, there is the possibility that the chip would break when the chip is pushed with a needle from the carrier substrate side.

In view of the problems described above, an object of the present disclosure is to provide a bonding device and a bonding method with which it is possible to easily carry out bonding that is accompanied by activation of bonding surfaces.

In order to solve the problems described above, a bonding device according to the present disclosure is a bonding device configured to bond a first element and a second element, the bonding device comprising an activating unit configured to activate a first bonding surface, which is a bonding surface of the first element, and a second bonding surface, which is a bonding surface of the second element, and a bonding unit configured to irradiate an active energy ray to cause the first bonding surface and the second bonding surface to come closer and bond with each other, from a state in which the first bonding surface and the second bonding surface face each other with a prescribed gap therebetween.

In this bonding device, the bonding unit uses irradiation of an active energy ray to cause the first bonding surface and the second bonding surface to come closer to each other, so it becomes unnecessary to remove and transport a given first element from a collection of first elements. Therefore, the first element can be brought closer to the second element without causing any physical contact with the first bonding surface of the first element during the process, so that it is possible to bond the first element and the second element without disrupting the activated state of the bonding surfaces.

In addition, a first holding substrate that holds the first element can be provided with a blistering layer in which blistering occurs due to irradiation of the active energy ray, and the blistering can cause the first element to come closer to the second element in a state of being held by the blistering layer.

As a result, it is possible to reliably bring the first element closer to the second element.

In addition, a first holding substrate that holds the first element can be provided with an adhesive layer in which ablation occurs due to irradiation of the active energy ray, and the ablation can cause the first element to detach from the first holding substrate while being biased and to come closer to the second element.

As a result, it is possible to reliably bring the first element closer to the second element.

Additionally, the bonding unit can be configured to irradiate the active energy ray to cause the first bonding surface and the second bonding surface to come closer to each other, and to press the first bonding surface and the second bonding surface together with a prescribed amount of pressure.

As a result, it is possible to promote bonding between the first bonding surface and the second bonding surface.

In addition, the activating unit can be configured to expose the first bonding surface and the second bonding surface to a plasma atmosphere to activate each surface.

In order to solve the problems described above, a bonding method according to the present disclosure is a bonding method for bonding a first element and a second element, the bonding method comprising activating a first bonding surface, which is a bonding surface of the first element, and a second bonding surface, which is a bonding surface of the second element, and irradiating an active energy ray to cause the first bonding surface and the second bonding surface to come closer and bond with each other, from a state in which the first bonding surface and the second bonding surface face each other with a prescribed gap therebetween.

With this bonding method, in the irradiating of the active energy ray, irradiation of the active energy ray is used to cause the first bonding surface and the second bonding surface to come closer to each other, so it becomes unnecessary to remove and transport a given first element from a collection of first elements. Therefore, the first element can be brought closer to the second element without causing any physical contact with the first bonding surface of the first element during the process, so that it is possible to bond the first element and the second element without disrupting the activated state of the bonding surfaces.

According to the bonding device and bonding method of the present disclosure, it is possible to easily carry out bonding that is accompanied by activation of the bonding surfaces.

### BRIEF DESCRIPTION OF THE DRAWINGS

FIG. 1 is a diagram for explaining a bonding device according to one embodiment of the present disclosure.

FIG. 2 is a diagram for explaining a bonding unit in the present embodiment.

FIG. 3 is a diagram for explaining a mode of bonding elements according to the bonding of the present embodiment.

FIG. 4 is a diagram for explaining a mode of bonding elements according to another embodiment of the present disclosure.

### DETAILED DESCRIPTION OF EMBODIMENTS

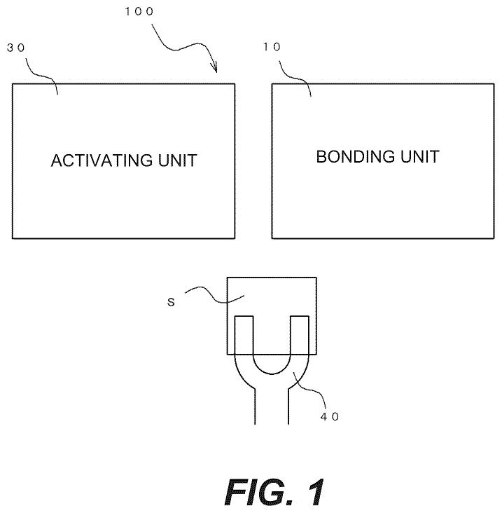

A bonding device according to one embodiment of the present disclosure will be described, with reference to FIG. 1.

A bonding device 100 comprises an activating unit 30 and a bonding unit 10, and bonds, with the bonding unit 10, elements whose bonding surfaces have been activated by the activating unit 30. Here, an element having a bonding surface may be in the form of a chip, such as a semiconductor chip, or in the form of a substrate, such as a circuit board. A plurality of chip-like elements are arranged in an array and held by a transfer substrate, and transport of the elements between the activating unit 30 and the bonding unit 10 is carried out in the form of a substrate by a transport robot 40.

The activating unit 30 is a plasma processing device that has a chamber for accommodating a first element and a second element and a plasma generator for creating a plasma atmosphere inside the chamber, thereby exposing a first bonding surface of the first element and a second bonding surface of the second element to the plasma atmosphere. The first bonding surface and the second bonding surface are each activated by being exposed to the plasma atmosphere in this manner. Activate means to put the surface of a substance in a state in which chemical reactions can easily occur. In addition, the process of activating the first bonding surface and the second bonding surface is referred to as the activation step in this description. In the illustrated embodiment, the plasma generator applies an electromagnetic field to a gas within the chamber, causing the gas to ionize and form plasma.

When activation of the first bonding surface of the first element and the second bonding surface of the second element carried out by the activating unit 30 is completed, the second element and the first element are transported, in that order, to the bonding unit 10 by the transport robot 40. In the present embodiment, the first element is a plurality of semiconductor chips arranged and held on a transfer substrate, and the second element is a circuit board, as described further below.

The transport robot 40 has an essentially U-shaped robot hand and a movement mechanism for moving said robot hand, such as an actuator, and uses suction to respectively hold a surface of the transfer substrate on the opposite side of the surface holding the first element, and a surface of the second element on the opposite side of the second bonding surface, to transport the transfer substrate and the second element from the activating unit 30 to the bonding unit 10.

The robot hand may have an inverting function. In this case, the second element may be transported to the bonding unit 10 first, then suction may be used to hold the transfer substrate, which is transported to the bonding unit 10 while being inverted, so that the first bonding surface and the second bonding surface face each other in the bonding unit 10 while the robot hand continues to use suction to hold the transfer substrate.

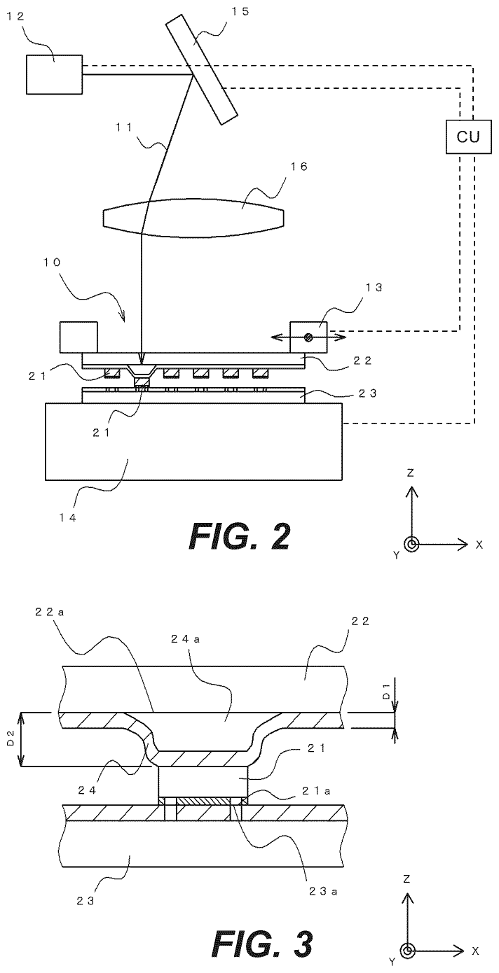

The bonding unit 10 of the present embodiment is shown in FIG. 2.

The bonding unit 10 is a transfer device, comprising a laser irradiation unit 12 that irradiates laser light 11, a transfer substrate holding unit 13 that can hold and move a transfer substrate 22 at least in an X-axis direction and a Y-axis direction, a receiving substrate holding unit 14 that is below the transfer substrate holding unit 13 and holds a receiving substrate 23 so as to face the transfer substrate 22 with a gap therebetween, and a control unit or electronic controller CU. The bonding unit 10 irradiates the laser light 11 onto the transfer substrate 22 to generate ablation in the transfer substrate, thereby transferring an element 21 from the transfer substrate 22 to the receiving substrate 23.

Since it is necessary to maintain a state in which the bonding surface of the element is activated in the bonding unit 10, a reduced-pressure environment is preferably formed inside the bonding unit 10 (the transfer device).

The laser irradiation unit 12 is a laser (e.g., a laser emitter device) that irradiates the laser light 11, such as an excimer laser, which is an active energy ray, and is provided fixed to the bonding unit 10 (the transfer device). In the present embodiment, the laser irradiation unit 12 irradiates the spot-shaped laser light 11, the irradiation position of the laser light 11 in the X-axis direction and the Y-axis direction is controlled via an fθ lens 16 and a galvano mirror 15 whose angle is adjusted by the control unit CU, and the laser light 11 selectively irradiates a plurality of the elements 21 arranged on the transfer substrate 22 held by the transfer substrate holding unit 13. When the laser light 11 enters near the element 21 through the transfer substrate 22, blistering occurs between the transfer substrate 22 and the element 21 due to the application of active energy (light energy). This blistering causes the element 21 to move toward the receiving substrate 23, and the bonding surfaces of the element 21 and the receiving substrate 23 come closer to each other. In the illustrated embodiment, the control unit CU includes at least one processor having a CPU (Central Processing Unit) and a storage device or computer memory, and an interface for each device is included as necessary. The control unit CU is operatively coupled to the laser irradiation unit 12 to control the timing and intensity of the irradiation of the laser light 11 by the laser irradiation unit 12. The control unit CU is also operatively coupled to electronic actuators of the galvano mirror 15 to adjust the angle of the galvano mirror 15, thereby adjusting the position of the irradiation of the laser light 11 on the transfer substrate 22. With this configuration, the control unit CU can control the size and location of the blistering occurred between the transfer substrate 22 and the element 21 in a manner described below.

In this description, the element 21 is a semiconductor chip, such as a logic device or a memory unit, and is hereinafter also referred to as chip 21. One surface of the chip 21 is provided with a bonding surface 21a, which is a smooth surface on which is formed wiring for achieving electrical connection with the wiring substrate, as shown in FIG. 3.

The transfer substrate holding unit 13 has an opening, and uses suction to hold the vicinity of the outer periphery of the transfer substrate 22. It is possible to irradiate the laser light 11 that is emitted from the laser irradiation unit 12 onto the transfer substrate 22, which is held by the transfer substrate holding unit 13, via this opening. As described above, a transport robot hand that transports a substrate S between the activating unit 30 and the bonding unit 10 may also serve as this transfer substrate holding unit 13.

The transfer substrate 22 is a substrate made of glass, or the like, that can transmit the laser light 11, and that holds a plurality of the chips 21 on the bottom surface side thereof. In addition, an adhesive layer 24 is formed on the surface of the transfer substrate 22 that holds the chip 21, as shown in FIG. 3, and the surface of this adhesive layer 24 has adhesiveness. The adhesive force of this surface of the adhesive layer 24 serves as the holding force for the chips 21, thereby adhesively holding the chips 21. In the present description, a substrate that holds an element (chip 21) such as the transfer substrate 22 is also referred to as a first holding substrate.

In addition, the transfer substrate holding unit 13 has a movement mechanism, such as at least one electronic actuator, to move relative to the receiving substrate holding unit 14 in at least the X-axis direction and the Y-axis direction. In particular, the control unit CU is operatively coupled to the movement mechanism of the transfer substrate holding unit 13 to control the movement mechanism for adjusting the position of the transfer substrate holding unit 13. Thus, it is possible to adjust the relative position of the chip 21 held by the transfer substrate 22 relative to the receiving substrate 23. Furthermore, the transfer substrate holding unit 13 also includes an electronic actuator that is operatively connected to the control unit CU to generate suction force to hold the vicinity of the outer periphery of the transfer substrate 22.

The receiving substrate holding unit 14 has a flat upper surface, and, during the transfer step of the chip 21, holds the receiving substrate 23 such that adhesive layer 24 of the transfer substrate 22 and the chip 21 held by the adhesive layer 24 face the receiving surface of the receiving substrate 23 with a prescribed gap therebetween. A plurality of suction holes are provided on the upper surface of the receiving substrate holding unit 14, which hold the rear surface of the receiving substrate 23 (the surface on which the chips 21 are not transferred) using suction force. Thus, the receiving substrate holding unit 14 also includes an electronic actuator that is operatively connected to the control unit CU to generate the suction force to hold the rear surface of the receiving substrate 23.

Here, the receiving substrate 23 in the present embodiment is a substrate to which semiconductor chips are bonded, and is a circuit board on which is provided wiring for achieving electrical connection with the chip 21. At least the surface to which the chip 21 is bonded is provided with wiring and is a smooth surface.

In the present embodiment, only the transfer substrate holding unit 13 is moved in the X-axis direction and the Y-axis direction to move the transfer substrate holding unit 13 and the receiving substrate holding unit 14 relative to each other, but if the dimensions of the receiving substrate 23 are large and the entire surface of the receiving substrate 23 cannot be placed directly below the irradiation range of the laser light 11, the receiving substrate holding unit 14 may also be provided with a movement mechanism, such as at least one electronic actuator, in the X-axis direction and the Y-axis direction. In this case, the control unit CU is operatively coupled to the movement mechanism of the receiving substrate holding unit 14 to control the movement mechanism for adjusting the position of the receiving substrate holding unit 14.

A mode by which the chip 21 of the present disclosure is bonded by the bonding unit 10 (the transfer device) of the present embodiment will be described, with reference to FIG. 3. The operations of the bonding unit 10 described below are basically controlled by the control unit CU, unless otherwise described.

As described above, the adhesive layer 24 is formed on the surface of the transfer substrate 22 that holds the chip 21. This adhesive layer 24 has an adhesive surface, as well as a property in which blistering occurs in the adhesive layer 24 or between the adhesive layer 24 and a glass surface 22a of the transfer substrate 22 due to irradiation of the laser light 11. The surface of the chip 21 opposite to the bonding surface is adhesively held by this adhesive layer 24.

Here, the laser light 11 is irradiated toward the chip 21 through the transfer substrate 22 in a state in which the transfer substrate 22 and the receiving substrate 23 are facing each other across the chip 21, and the laser light 11 is irradiated on the portion of the adhesive layer 24 that is adhesively holding the chip 21 (that is, the vicinity of the chip 21); as a result, the energy of the laser light 11 decomposes a part of the material of the adhesive layer 24, generating gas. Due to the decomposition of the material of the adhesive layer 24 and the generation of gas, a blister (air bubble) 24a is generated inside the adhesive layer 24 or between the adhesive layer 24 and the glass surface 22a of the transfer substrate 22. The phenomenon in which the blister 24a is generated in this manner is referred to as blistering in this description. In addition, a layer in which blistering occurs as a result of imparting energy, such as the adhesive layer 24 of the present embodiment, is also referred to as a blistering layer in this description.

A distance D2 between the surface of the adhesive layer 24 and the glass surface 22a where such blistering has occurred is larger than a distance D1 between the surface of the adhesive layer 24 and the glass surface 22a before blistering occurs. Therefore, when blistering occurs in the adhesive layer 24 at a position where the chip 21 is held, the chip 21 separates from the glass surface 22a of the transfer substrate 22 while being held on the surface portion of the adhesive layer 24.

In the present embodiment, since the receiving substrate 23 is provided near, and facing, the chip 21 with a prescribed gap therebetween, the chip 21 approaches the receiving substrate 23 as a result of the generation of the blistering, while being held on the surface portion of the adhesive layer 24.

Then, if the distance between the receiving substrate 23 and the chip 21 before the blistering is smaller than the amount of positional variation of the surface of the adhesive layer 24 that could occur due to the generation of blistering, the chip 21 is brought closer to the receiving substrate 23 and may further be pressed due to the generation of the blistering.

Coming closer in this description means approaching to a distance at which electron orbits of the two target surfaces overlap; as a result of activated bonding surfaces coming closer to each other, bonding between the bonding surfaces begins regardless of the presence or absence of external force.

Therefore, it is possible for the bonding unit 10 to bond the bonding surface 21a of the chip 21 and a bonding surface 23a of the receiving substrate 23, under a condition in which the bonding surfaces of both the chip 21 and the receiving substrate 23 are activated in advance by the activating unit 30.

In addition, in the present embodiment, blistering is generated in the adhesive layer 24 to cause the chip 21 to come closer to the receiving substrate 23 while being held on the surface portion of the adhesive layer 24, so it is possible to press the chip 21 against the receiving substrate 23 using the kinetic energy caused by the blistering during a prescribed period of time until the blisters 24a shrinks, thereby promoting bonding between the activated bonding surfaces. Here, the pressing force to press the chip 21 against the receiving substrate 23 can be generated while the transfer substrate holding unit 13 and the receiving substrate holding unit 14 are stationary relative to each other. In other words, the pressing force to press the chip 21 against the receiving substrate 23 can be generated without relatively moving the transfer substrate holding unit 13 and the receiving substrate holding unit 14 toward each other.

In addition, the pressing force caused by this blistering is smaller than the pressing force caused by the ablation described further below, and is able to press the chip 21 against the receiving substrate 23 more gently and for longer than in the bonding by ablation.

If the bonding strength between the receiving substrate 23 and the chip 21 when the blister 24a shrinks is larger than the adhesive force of the chip 21 due to the adhesive layer 24, the bonded state between the chip 21 and the receiving substrate 23 is maintained.

In addition, the intensity of the laser light 11 can be adjusted to adjust the size of the blister 24a, thereby adjusting the pressing force of the chip 21 against the receiving substrate 23.

Additionally, as described above, a process for irradiating an active energy ray to cause the first bonding surface and the second bonding surface to come closer and bond with each other, from a state in which the first bonding surface and the second bonding surface face each other with a prescribed gap therebetween, is also referred to as the bonding step in this description.

With such a bonding step, it is possible to bring the chip 21 closer to the receiving substrate 23 without requiring a step for removing and transporting the chip 21 from a collection of chips. As a result, it is possible to bring the chip 21 closer to the receiving substrate 23 without causing any physical contact with the bonding surface 21a of the chip 21 during the process, so that the chip 21 and the receiving substrate 23 can be bonded without disrupting the activated state of the bonding surfaces.

In addition, after the chip 21 and the receiving substrate 23 are bonded, for example, the transfer substrate holding unit 13 may be operated to raise the transfer substrate 22 and separate the transfer substrate 22 and the receiving substrate 23, to remove the adhesive layer 24 from the chip 21.

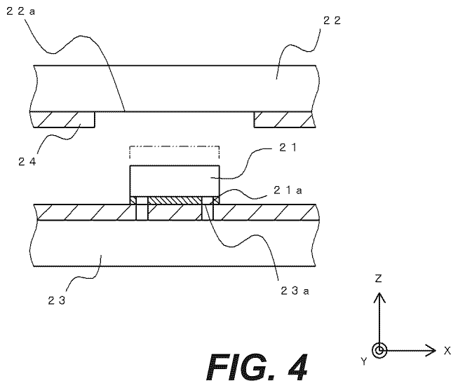

A mode of bonding elements according to another embodiment of the present disclosure is shown in FIG. 4. The operations of the bonding unit 10 described below are also controlled by the control unit CU, unless otherwise described.

In the bonding mode of the aforementioned embodiment, blistering is generated in the adhesive layer 24 by irradiating the laser light 11 to bring the chip 21 closer to the receiving substrate 23, but in the bonding mode of the present embodiment, ablation is generated in the adhesive layer 24 to bring the chip 21 closer the receiving substrate 23.

Specifically, the laser light 11 is irradiated toward the chip 21 through the transfer substrate 22 in a state in which the transfer substrate 22 and the receiving substrate 23 are facing each other across the chip 21, and the laser light 11 is irradiated on the portion of an ablation layer 24 that is adhesively holding the chip 21 (that is, the vicinity of the chip 21); as a result, the material of the adhesive layer 24 is decomposed, is melted, and disappears due to the application of active energy (light energy), generating gas. Due to the generation of gas accompanying the disappearance of the adhesive layer 24, the chip 21 is detached form the transfer substrate 22 and is biased to move in a direction away from the transfer substrate 22. That is, laser lift-off is carried out.

In addition, a layer in which ablation occurs as a result of application of energy, such as the adhesive layer 24 of the present embodiment, is also referred to as an ablation layer in this description.

In the present embodiment, since the receiving substrate 23 is provided near, and facing, the chip 21 with a prescribed gap therebetween, the chip 21 that is biased by the laser lift-off flies toward the receiving substrate 23 and comes closer to the receiving substrate 23. Then, the bonding surface 21a of the chip 21 and the bonding surface 23a of the receiving substrate 23 that have come closer to each other begin to be bonded, under a condition in which the bonding surfaces of both the chip 21 and the receiving substrate 23 are activated in advance by the activating unit 30, in the same manner as in the previous embodiment.

In addition, in the present embodiment, the chip 21 is completely separated from the transfer substrate 22 when the chip 21 comes closer the receiving substrate 23, so it is difficult to obtain a continuous pressing force at the time of bonding; however, the kinetic energy that is generated when the chip 21 collides with the receiving substrate 23 can instantaneously press the chip 21 against the receiving substrate 23, thereby promoting bonding between the activated bonding surfaces.

According to the bonding device and bonding method described above, it is possible to easily carry out bonding that is accompanied by activation of bonding surfaces.

Here, the bonding device and the bonding method of the present disclosure are not limited to the embodiments described above, and may take other forms within the scope of the present disclosure. For example, in the foregoing description, the kinetic energy caused by blistering or ablation of the adhesive layer of the transfer substrate presses the first element against the second element, thereby promoting bonding between the first bonding surface and the second bonding surface, but the present disclosure is not limited thereto; a separate pressure-bonding step may be provided.

In addition, in the foregoing description, the activating unit and the bonding unit are separate devices, but no limitation is imposed thereby; a single device may serve as both the activating unit and the bonding unit. Then, the transfer substrate holding unit may hold the rear surface side of the transfer substrate, the bonding surface may be activated by plasma, or the like, in a state in which the receiving substrate holding unit holds the rear surface side of the receiving substrate, and the chip may be transferred onto the receiving substrate by irradiation of an active energy ray while maintaining the state in which the transfer substrate holding unit and the receiving substrate holding unit are holding the transfer substrate and the receiving substrate.

### DESCRIPTIONS OF THE REFERENCE SYMBOLS

10 Bonding unit (transfer device)
11 Laser light (active energy ray)
12 Laser light source
13 Transfer substrate holding unit
14 Receiving substrate holding unit
15 Galvano mirror
16y Fθ lens
21 Chip (element)
21a Bonding surface
22 Transfer substrate
22a Glass surface
23 Receiving substrate (circuit board)
23a Bonding surface
24 Adhesive layer
24a Blister
30 Activating unit
40 Robot hand
100 Bonding device
S Substrate

What is claimed is:

1. A bonding device configured to bond a first element and a second element, the bonding device comprising:
an activating unit configured to activate a first bonding surface, which is a bonding surface of the first element, and a second bonding surface, which is a bonding surface of the second element; and
a bonding unit configured to irradiate an active energy ray to cause the first bonding surface and the second bonding surface to come closer and bond with each other, from a state in which the first bonding surface and the second bonding surface face each other with a prescribed gap therebetween.

2. The bonding device according to claim 1, wherein
a first holding substrate that holds the first element is provided with a blistering layer in which blistering occurs due to irradiation of the active energy ray, and the blistering causes the first element to come closer to the second element in a state of being held by the blistering layer.

3. The bonding device according to claim 1, wherein
a first holding substrate that holds the first element is provided with an adhesive layer in which ablation occurs due to irradiation of the active energy ray, and the ablation causes the first element to detach from the first holding substrate while being biased and to come closer to the second element.

4. The bonding device according to claim 1, wherein
the bonding unit is configured to irradiate the active energy ray to cause the first bonding surface and the second bonding surface to come closer to each other, and to press the first bonding surface and the second bonding surface together with a prescribed amount of pressure.

5. The bonding device according to claim 1, wherein
the activating unit is configured to expose the first bonding surface and the second bonding surface to a plasma atmosphere to activate each surface.

6. The bonding device according to claim 2, wherein
the bonding unit is configured to irradiate the active energy ray to cause the first bonding surface and the second bonding surface to come closer to each other, and to press the first bonding surface and the second bonding surface together with a prescribed amount of pressure.

7. The bonding device according to claim 3, wherein
the bonding unit is configured to irradiate the active energy ray to cause the first bonding surface and the second bonding surface to come closer to each other, and to press the first bonding surface and the second bonding surface together with a prescribed amount of pressure.

8. The bonding device according to claim 2, wherein
the activating unit is configured to expose the first bonding surface and the second bonding surface to a plasma atmosphere to activate each surface.

9. The bonding device according to claim 3, wherein
the activating unit is configured to expose the first bonding surface and the second bonding surface to a plasma atmosphere to activate each surface.

10. The bonding device according to claim 4, wherein
the activating unit is configured to expose the first bonding surface and the second bonding surface to a plasma atmosphere to activate each surface.

11. The bonding device according to claim 6, wherein
the activating unit is configured to expose the first bonding surface and the second bonding surface to a plasma atmosphere to activate each surface.

12. The bonding device according to claim 7, wherein
the activating unit is configured to expose the first bonding surface and the second bonding surface to a plasma atmosphere to activate each surface.

13. A bonding method for bonding a first element and a second element, the bonding method comprising:
activating a first bonding surface, which is a bonding surface of the first element, and a second bonding surface, which is a bonding surface of the second element; and
irradiating an active energy ray to cause the first bonding surface and the second bonding surface to come closer and bond with each other, from a state in which the first bonding surface and the second bonding surface face each other with a prescribed gap therebetween.
